(19) United States
(12) Patent Application Publication
(10) Pub. No.: US 2025/0392840 A1
(43) Pub. Date: Dec. 25, 2025

(54) IMAGE SENSOR

(71) Applicant: VisEra Technologies Company Ltd., Hsin-Chu City (TW)

(72) Inventors: Hsien-Shu LIAO, Hsin-Chu City (TW); Chia-Chi CHOU, Hsin-Chu City (TW); Cheng-Hsuan LIN, Hsin-Chu City (TW)

(21) Appl. No.: 18/750,580

(22) Filed: Jun. 21, 2024

(51) Int. Cl. H04N 25/70; H04N 25/11

(52) U.S. Cl. CPC H04N 25/70; H04N 25/11

(57) ABSTRACT

An image sensor includes a first quad phase detection (QPD) unit. The first QPD unit includes four photodiodes arranged in a matrix of two rows and two columns, a deep trench isolation structure including an outer wall surrounding the matrix of the photodiodes and an inner wall separating the photodiodes, a grid disposed on the deep trench isolation structure, a color filter disposed on the photodiodes and filled in the grid, and an optical component disposed on the color filter. The optical component includes a ring-type lens and a center lens surrounded by the ring-type lens, in which the ring-type lens has portions overlapping the outer wall of the deep trench isolation structure.

### BACKGROUND

### Field of Invention

The present disclosure relates to an image sensor.

### Description of Related Art

Solid-state image sensors (e.g., charge-coupled device (CCD) image sensors, complementary metal-oxide semiconductor (CMOS) image sensors, and so on) have been widely used in various image-capturing apparatuses such as digital still-image cameras, digital video cameras, and the like. The light-sensing portion in the solid-state image sensor may be formed at each of pixels, and signal electric charges may be generated according to the amount of light received in the light-sensing portion. In addition, the signal electric charges generated in the light-sensing portion may be transmitted and amplified, whereby an image signal is obtained.

In traditional multi-PD (i.e., one color filter corresponds to two, four, or more photo diodes) solid-state image sensor, after light with long wavelength enters the solid-state image sensor, it may be focused on the isolation structure (e.g., deep trench isolations (DTI)), which may cause strong scattering and generate crosstalk. Therefore, there are still various challenges in the design and manufacturing of solid-state image sensors.

### SUMMARY

An aspect of the disclosure provides an image sensor. The image sensor includes a first quad phase detection (QPD) unit. The first QPD unit includes four photodiodes arranged in a matrix of two rows and two columns, a deep trench isolation structure including an outer wall surrounding the matrix of the photodiodes and an inner wall separating the photodiodes, a grid disposed on the deep trench isolation structure, a color filter disposed on the photodiodes and filled in the grid, and an optical component disposed on the color filter. The optical component includes a ring-type lens and a center lens surrounded by the ring-type lens, in which the ring-type lens has portions overlapping the outer wall of the deep trench isolation structure.

In some embodiments, the ring-type lens and the center lens are made of the same material, and a refractive index of the ring-type lens and the center lens is in a range from 1.5 to 2.5.

In some embodiments, a height of the ring-type lens is less than a height of the center lens, and a dimension of the ring-type lens is less than a dimension of the center lens.

In some embodiments, a ratio of a height of the ring-type to a height of the center lens is in a range from 45% to 65%.

In some embodiments, a ratio of a dimension of the ring-type lens to a color pitch size is in a range from 14% to 25%, in which the color pitch size is a distance between centers of opposite portions of the grid.

In some embodiments, a tangent line of the ring-type lens aligns a longitudinal axis of the outer wall of the deep trench isolation structure.

In some embodiments, a tangent line of the ring-type lens is shifted relative to a longitudinal axis of the outer wall of the deep trench isolation structure, and a shifting between the tangent line of the ring-type lens and the longitudinal axis of the outer wall of the deep trench isolation structure is equal to or less than 50 nm.

In some embodiments, a shape of an outer profile of the ring-type lens is same as a shape of an inner profile of the ring-type lens.

In some embodiments, a shape of an outer profile of the ring-type lens is different from a shape of an inner profile of the ring-type lens.

In some embodiments, the center lens overlaps the four photodiodes.

In some embodiments, the center lens overlaps adjacent two of the photodiodes, and the image sensor further includes an additional optical component disposed on the color filter and overlapping the other two of the photodiodes. The additional optical component includes a ring-type lens and a center lens surrounded by the ring-type lens, in which the ring-type lens has portions overlapping the outer wall of the deep trench isolation structure.

In some embodiments, the image sensor further includes a second QPD unit. The second QPD unit includes four photodiodes arranged in a matrix of two rows and two columns, a deep trench isolation structure including an outer wall surrounding the matrix of the photodiodes and an inner wall separating the photodiodes, a color filter disposed on the photodiodes, and an optical component disposed on the color filter. A waveband of the color filter of the second QPD unit is different from a waveband of the first QPD unit.

In some embodiments, the optical component of the second QPD unit includes a ring-type lens and a center lens surrounded by the ring-type lens, in which the ring-type lens has portions overlapping the outer wall.

In some embodiments, the ring-type lens of the first QPD unit is merged with the ring-type lens of the second QPD unit.

In some embodiments, a shape of the optical component of the first QPD unit is different from the optical component of the second QPD unit.

In some embodiments, a filling factor of the ring-type lens of the first QPD unit is different from a filling factor of the ring-type lens of the second QPD unit.

In some embodiments, the optical component of the second QPD unit includes four sphere lenses disposed on the photodiodes, respectively.

In some embodiments, the optical component of the second QPD unit includes a single sphere lenses disposed on the photodiodes.

In some embodiments, the image sensor further includes a second QPD unit. The second QPD unit includes four photodiodes arranged in a matrix of two rows and two columns, a deep trench isolation structure including an outer wall surrounding the matrix of the photodiodes and an inner wall separating the photodiodes, a color filter disposed on the photodiodes, a first optical component, and a second optical component. A waveband of the color filter of the second QPD unit is different from a waveband of the first QPD unit. The first optical component is disposed on the color filter and above adjacent two of the photodiodes. The first optical component includes a ring-type lens and a center lens surrounded by the ring-type lens, in which the ring-type lens has portions overlapping the outer wall. The second optical component is disposed on the color filter and above another two of the photodiodes. The second optical component includes a ring-type lens and a center lens surrounded by the ring-type lens, in which the ring-type lens has portions overlapping the outer wall.

In some embodiments, the image sensor further includes a second QPD unit. The second QPD unit includes four photodiodes arranged in a matrix of two rows and two columns, a deep trench isolation structure including an outer wall surrounding the matrix of the photodiodes and an inner wall separating the photodiodes, a color filter disposed on the photodiodes, and four optical components disposed on the color filter and above the photodiodes, respectively. A waveband of the color filter of the second QPD unit is different from a waveband of the first QPD unit. Each of the optical components includes a ring-type lens and a center lens surrounded by the ring-type lens, in which the ring-type lens has a portion overlapping the outer wall.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a cross-sectional view of a portion of an image sensor according to some embodiments of the disclosure.

FIG. 2 is a top view of a quad phase detection (QPD) unit of the image sensor according to some embodiments of the disclosure.

FIG. 3A and FIG. 3B are a cross-sectional view and a top view of QPD unit of the image sensor according to some embodiments of the disclosure, respectively.

FIG. 4A and FIG. 4B are a cross-sectional view and a top view of QPD unit of the image sensor according to some embodiments of the disclosure, respectively.

FIG. 5A illustrates a top view of a conventional QPD unit having overlay issue.

FIG. 5B illustrates an operation mechanism of the conventional QPD unit having overlay issue.

FIG. 5C illustrates a top view of an embodiment of a QPD unit having overlay issue of the disclosure.

FIG. 5D illustrates an operation mechanism of the embodiment of the QPD unit having overlay issue.

FIG. 6A to FIG. 6F are top views of QPD units according to different embodiments of the disclosure.

FIG. 7A to FIG. 7I are top views of sets of QPD units according to different embodiments of the disclosure.

FIG. 8A to FIG. 8D are top views of an image sensor according to different embodiments of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

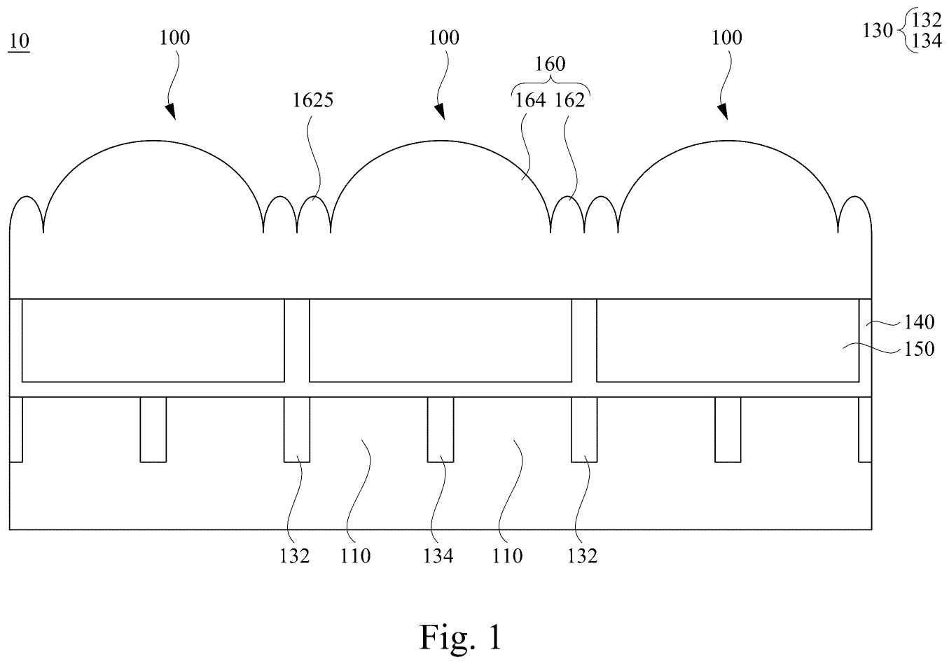

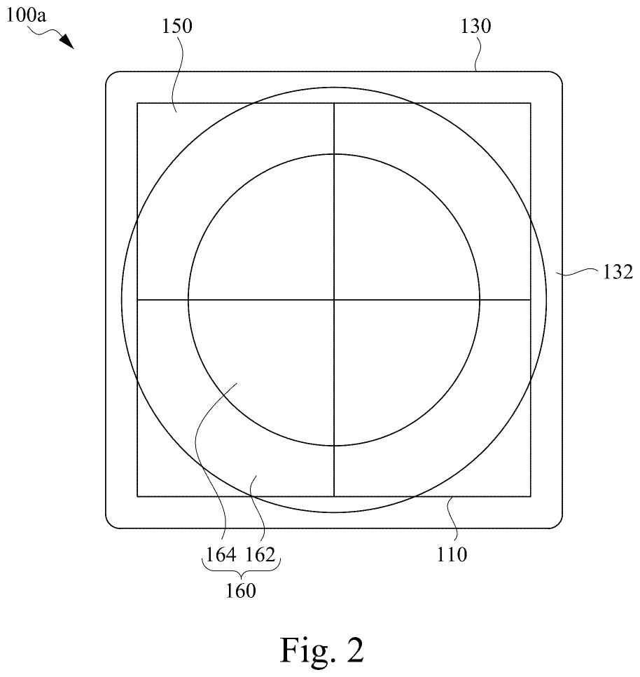

Reference is made to FIG. 1 and FIG. 2. FIG. 1 is a cross-sectional view of a portion of an image sensor according to some embodiments of the disclosure, and FIG. 2 is a top view of a quad phase detection (QPD) unit of the image sensor according to some embodiments of the disclosure. The image sensor 10 includes a plurality of QPD units 100 arranged in an array. Each of the QPD units 100 includes four photodiodes 110 formed in a substrate 120, and the photodiodes 110 are defined and spaced by a deep trench isolation (DTI) structure 130. The photodiodes 110 in the QPD unit 100 are arranged in a matrix of two rows and two columns. The DTI structure 130 includes an outer wall 132 surrounding the matrix of the photodiodes 110 and an inner wall 134 separating the photodiodes 110. The adjacent QPD units 100 share the outer wall 132 of the DTI structure 130.

Each of the QPD units 100 includes a grid 140 on the outer wall 132 of the DTI structure 130. The grid 140 defines an aperture, and each of the QPD units 100 includes a corresponding color filter 150 disposed on the photodiodes 110 and filled in the aperture defined by the grid 140. In some embodiments, each of the color filters 150 overlaps four photodiodes 110, and each of the photodiodes 110 is in a shape of square.

One of the QPD units 100, such as the QPD unit 100a of FIG. 2, includes an optical component 160 disposed on the color filter 150. The optical component 160 includes a ring-type lens 162 and a center lens 164 surrounded by the ring-type lens 162. The center lens 164 overlaps the four photodiodes 110 of the QPD unit 100a, and the ring-type lens 162 has portions 1625 overlapping the outer wall 132 of the DTI structure 130.

In some embodiments, the shape of the center lens 164 can be the same or different from the shape of the ring-type lens 162. For example, the shape of the center lens 164 is a circle, and the shape of the ring-type lens 162 is a circular ring, in top view. In some embodiments, the ring-type lens 162 and the center lens 164 are made of the same material, and a refractive index of the ring-type lens 162 and the center lens 164 is in a range from 1.5 to 2.5. In some embodiments, the ring-type lens 162 and the center lens 164 are made by the same processes, and the ring-type lens 162 is connected to the center lens 164.

Ideally, the incident light converged by the optical component 160 is split by the DTI structure 130 and is evenly distributed to the photodiodes 110 as incident light spots. However, in many situations, the incident light to the QPD unit 100 is not always in a normal direction, the incident light spot on the photodiodes 110 may shift and is asymmetric. Additionally, the QPD unit 100 is very sensitive to the shifting of the optical component 160 due to the photolithography overlay issue. In some situation, the QPD unit 100 at the chip edge with a greater incident light angle than that at the chip center would further suffer narrow window of overlay.

The optical component 160 is designed to compensate the light reception unbalance of the QPD unit 100 due to the shifting of the optical component 160 and/or the increased incident light angle. The optical component 160 including the ring-type lens 162 and the center lens 164 can provide more than one focus to the photodiodes 110.

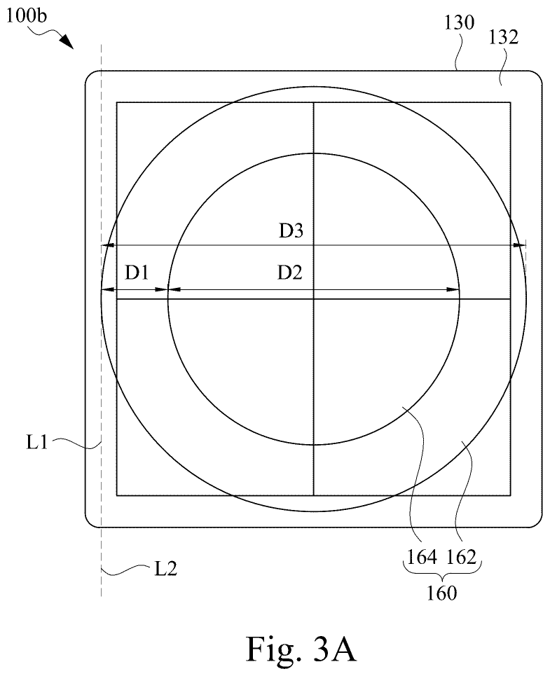

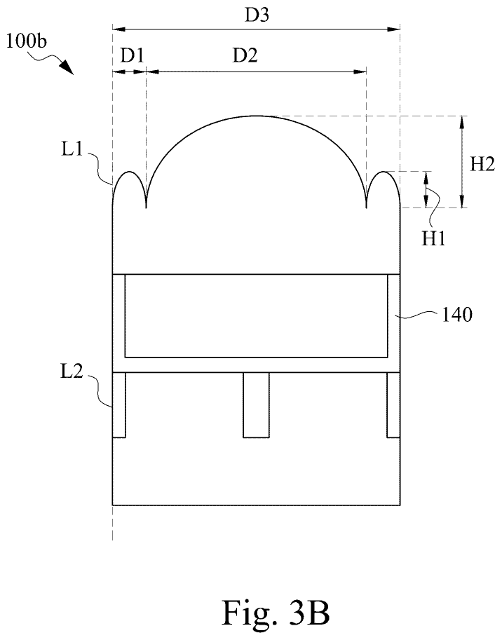

Reference is made to FIG. 3A and FIG. 3B. FIG. 3A and FIG. 3B are a cross-sectional view and a top view of QPD unit of the image sensor according to some embodiments of the disclosure, respectively. The optical component 160 of the QPD unit 100b includes the ring-type lens 162 and the center lens 164. The height H1 of the ring-type lens 162 is less than the height H2 of the center lens 164. In some embodiments, a ratio of the height H1 of the ring-type lens 162 to the height H2 of the center lens 164 is in a range from 45% to 65%. In some embodiments, the height H1 of the ring-type lens 162 is in a range from 0.25 μm to 0.35 μm.

In some embodiments, the dimension D1 of the ring-type lens 162 is less than the dimension D2 of the center lens 164. In some embodiments, a ratio of the dimension D1 of the ring-type lens 162 to a color pitch size D3 is in a range from 14% to 25%. The dimension D1 of the ring-type lens 162 and the dimension D2 of the center lens 164 are measured in the same direction, and the dimension D1 of the ring-type lens 162 is measured at the bottom of the solid portion of ring-type lens 162. The color pitch size D3 is a distance between centers of opposite portions of the grid 140. In some embodiments, the dimension D1 of the ring-type lens 162 is in a range from 0.20 μm to 0.30 μm.

In some embodiments, as shown in the QPD unit 100b of FIG. 3A and FIG. 3B, a tangent line L1 of the ring-type lens 162 of the optical component 160 of the QPD unit 100b aligns a longitudinal axis L2 of the outer wall 132 of the DTI structure 130, in which the longitudinal axis L2 of the outer wall 132 passes the center of the outer wall 132. In this embodiment, the optical component 160 is formed precisely as the layout design, and there is no overlay issue raised during the fabrication of the optical component 160.

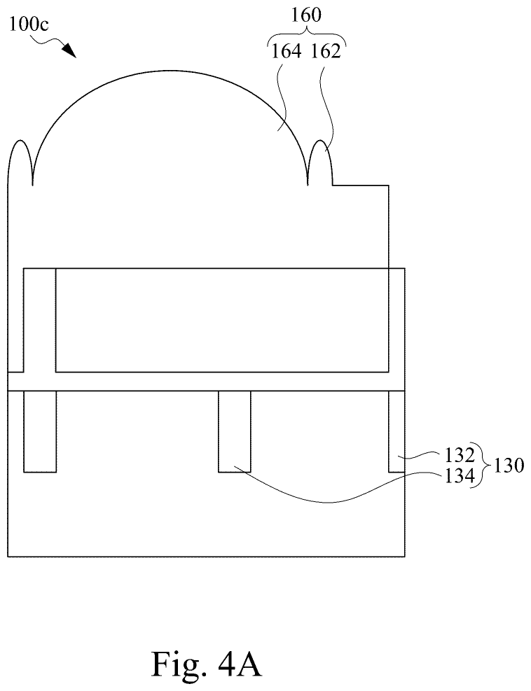

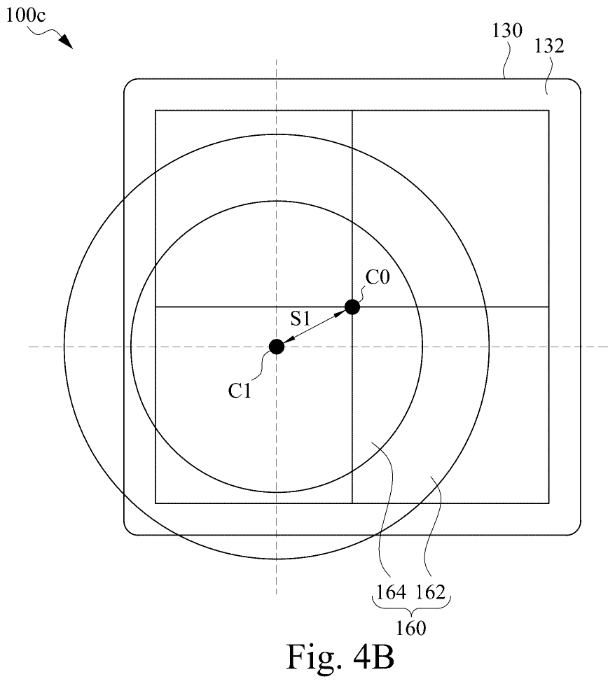

Reference is made to FIG. 4A and FIG. 4B. FIG. 4A and FIG. 4B are a cross-sectional view and a top view of QPD unit of the image sensor according to some embodiments of the disclosure, respectively. In some other embodiments, as shown in the QPD unit 100c, some unwanted and unpreventable overlay issues raised during the fabrication of the optical component 160, so that the center C1 of the optical component 160 is misaligned with the center C0 of the QPD unit 100c. In some embodiments, a shifting S1 between the center C1 of the optical component 160 and the center C0 of the QPD unit 100c is equal to or less than 50 nm.

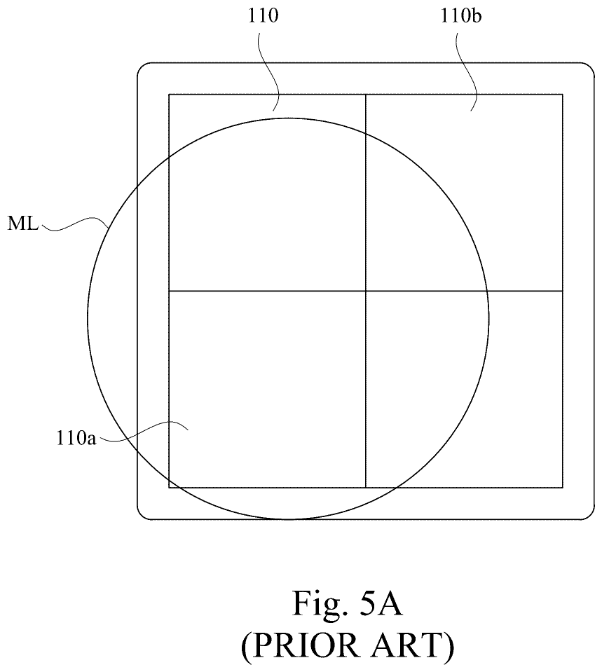

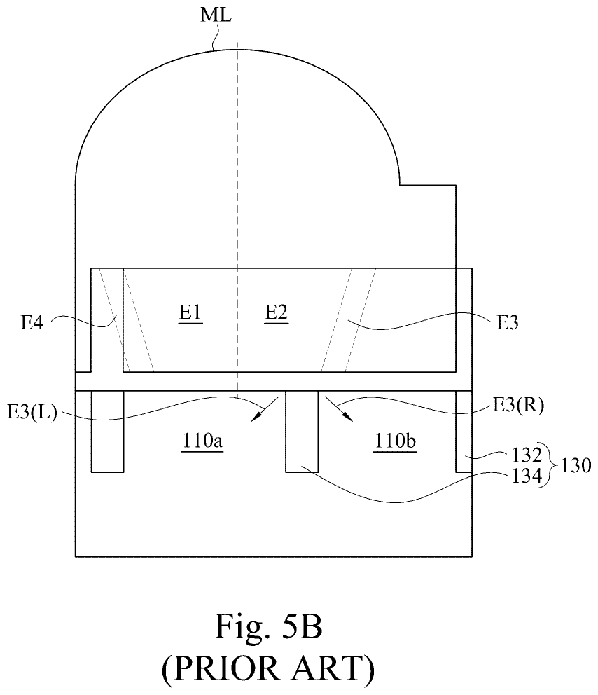

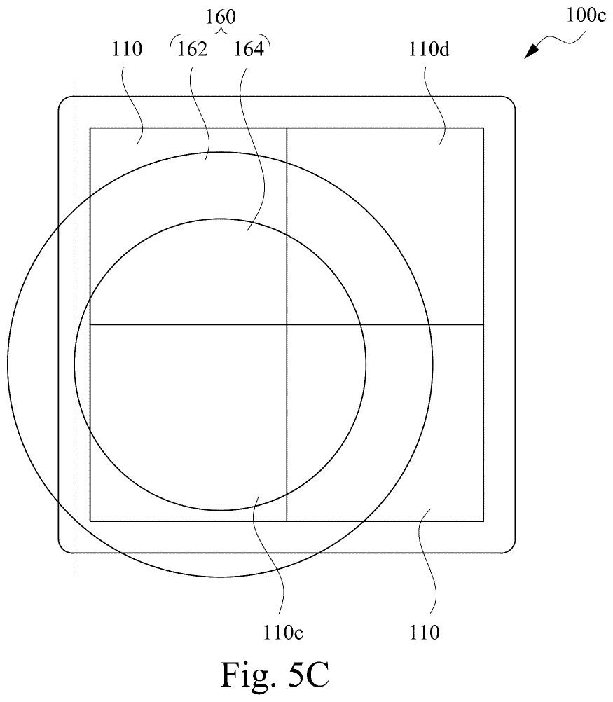

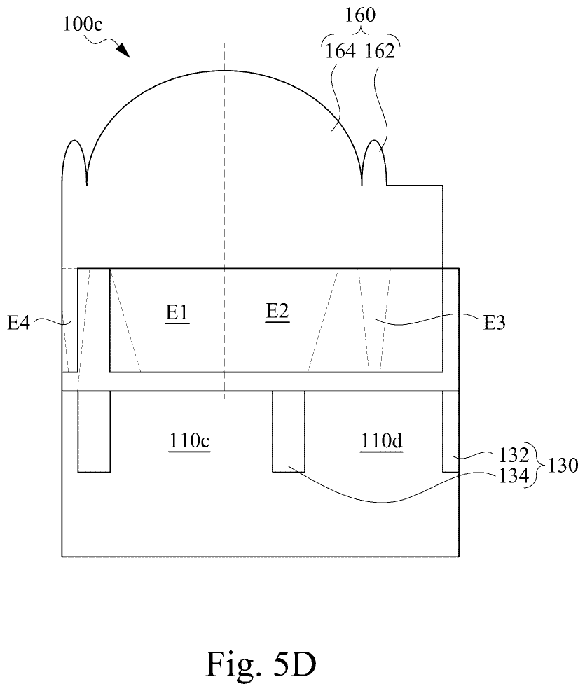

Reference is made to FIG. 5A and FIG. 5B. FIG. 5A illustrates a top view of a conventional QPD unit having overlay issue. FIG. 5B illustrates an operation mechanism of the conventional QPD unit having overlay issue, in which FIG. 5B is a cross-section taken along a diagonal axis of FIG. 5A. In FIG. 5A, the micro lens ML is disposed on the photodiodes 110, and the micro lens ML is shifted relative to the center of the photodiodes 110 because of the overlay issue. The photodiode 110a directly below the focus point of the micro lens ML has the maximum light receiving area, e.g. PD Max, and the diagonal photodiode 110b may have the minimum light receiving area, e.g. PD Min. The L/R balance is PD Max to PD Min. The L/R balance of the conventional QPD unit would be increased when the incident light enters the QPD unit with an incident angle.

As shown in FIG. 5B, the total energy E converged by the micro lens ML to the photodiode 110a (PD Max) and the photodiode 110b (PD Min) is E1+E2+E3+E4, in which E1 and E1 are corresponded to the center area of the micro lens ML, E3 and E4 are corresponded to the peripheral area of the micro lens ML, and E1, E1 and E2, E3 are symmetric. Because of the overlay issue, E3 is converged on the inner wall 134 of the DTI structure 130, rather than on the photodiode 110b. Energy E4 is almost entirely blocked by the grid 140 and can be regarded as zero. Energy E3 is separated by the inner wall 134 of the DTI structure 130, such that a portion of the Energy E3(L) is distributed on the photodiode 110a (PD Max), and a portion of the Energy E3(R) is distributed on the photodiode 110a (PD Min). L/R balance of the conventional QPD unit is (E1+E2+E3(L))/E3(R).

Reference is made to FIG. 5C and FIG. 5D. FIG. 5C illustrates a top view of an embodiment of a QPD unit having overlay issue of the disclosure. FIG. 5D illustrates an operation mechanism of the embodiment of the QPD unit having overlay issue, in which FIG. 5D is a cross-section taken along a diagonal axis of FIG. 5C. As shown in FIG. 5C, the optical component 160 of the QPD unit 100c includes the ring-type lens 162 and the center lens 164, and the optical component 160 can provide more than one focus to the photodiodes 110. For example, the optical component 160 is disposed on the photodiodes 110, and the optical component 160 is shifted relative to the center of the photodiodes 110 because of the overlay issue. The photodiode 110c is directly below the focus point of the center lens 164 and has the maximum light receiving area, e.g. PD Max, and the diagonal photodiode 110d may have the minimum light receiving area, e.g. PD Min.

As shown in FIG. 5D, the total energy E converged by the optical component 160 to the photodiode 110c (PD Max) and the photodiode 110d (PD Min) is E1+E2+E3+E4, in which E1 and E1 are corresponded to the center lens 164, E3 and E4 are corresponded to the ring-type lens 162, and E1, E1 and E2, E3 are symmetric. Because of the overlay issue, energy E4 is almost entirely out of the QPD unit 100c. Energy E3 is completely distributed on the photodiode 110a (PD Min) by the converging of the ring-type lens 162. L/R balance of the QPD unit 100c is (E1+E2)/E3, in which E3 is the sum of the E3(L) and E3(R) of FIG. 5B. The L/R balance of the QPD unit 100c is improved.

Please refer to Table 1, which is a simulation result of examples of conventional QPD units using only micro lens as the optical component and embodiments of the QPD units of the disclosure using center lens and ring-type lens as the optical component, under situations of different overlays. According to the simulation result, the L/R balances are getting worse when overlay amounts are getting greater, but the L/R balances of embodiments of the QPD units of the disclosure are always smaller than the L/R balances of the examples of conventional QPD units. The improvement ratio of the greater overlay such as with overlay 50 nm is better than the improvement ratio of the smaller overlay such as with overlay 20 nm. According to the simulation result, the embodiments of the QPD units of the disclosure using center lens and ring-type lens as the optical component can efficiently compensate the light reception unbalance and reduce the L/R balance when the overlay is within 50 nm.

TABLE 1

| | L/R balance (chip center) | | | | | | | | | | | |
|---|---|---|---|---|---|---|---|---|---|---|---|---|
| | w/i overlay 20 nm | | | w/i overlay 30 nm | | | w/i overlay 40 nm | | | w/i overlay 50 nm | | |
| | G | R | B | G | R | B | G | R | B | G | R | B |
| micro lens | 1.28 | 1.22 | 1.29 | 1.46 | 1.34 | 1.47 | 1.64 | 1.46 | 1.65 | 1.82 | 1.58 | 1.83 |
| center lens | 1.21 | 1.16 | 1.21 | 1.33 | 1.25 | 1.33 | 1.46 | 1.35 | 1.45 | 1.59 | 1.45 | 1.57 |
| and ring-type | | | | | | | | | | | | |
| lens | | | | | | | | | | | | |
| improvement | 5% | 5% | 6% | 9% | 7% | 10% | 11% | 8% | 12% | 13% | 8% | 14% |
| ratio | | | | | | | | | | | | |

Please refer to Table 2, which is a simulation result of examples of conventional QPD units using only micro lens as the optical component and embodiments of the QPD units of the disclosure using center lens and ring-type lens as the optical component, under situations of different positions on the chip. The incident angles at different positions of the chip are different. For example, the incident angle of the QPD unit at chip edge is greater than the incident angle of the QPD unit at chip center, so the quantum efficiency (QE) at the chip edge is worse than the QE at the chip center. The QEs of embodiments of the QPD units of the disclosure are always better than the QEs of the examples of conventional QPD units. The QE improvement ratio at the chip edge is better than the QE improvement ratio at the chip center.

TABLE 2

| | QE (Chip center) | | | QE (Chip edge) | | |
|---|---|---|---|---|---|---|
| | G | R | B | G | R | B |
| micro lens | 80.3 | 73.2 | 70.0 | 74.3 | 62.2 | 67.4 |
| center lens and ring- | 79.2 | 71.9 | 67.7 | 72.7 | 60.6 | 64.8 |
| type lens | | | | | | |
| improvement ratio | 1.4% | 1.8% | 3.3% | 2.2% | 2.6% | 3.9% |

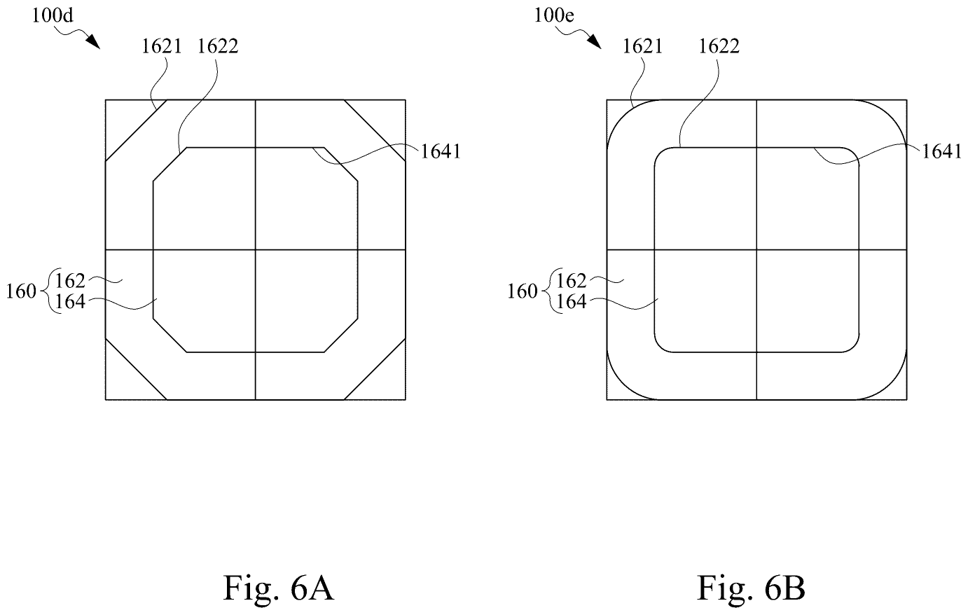

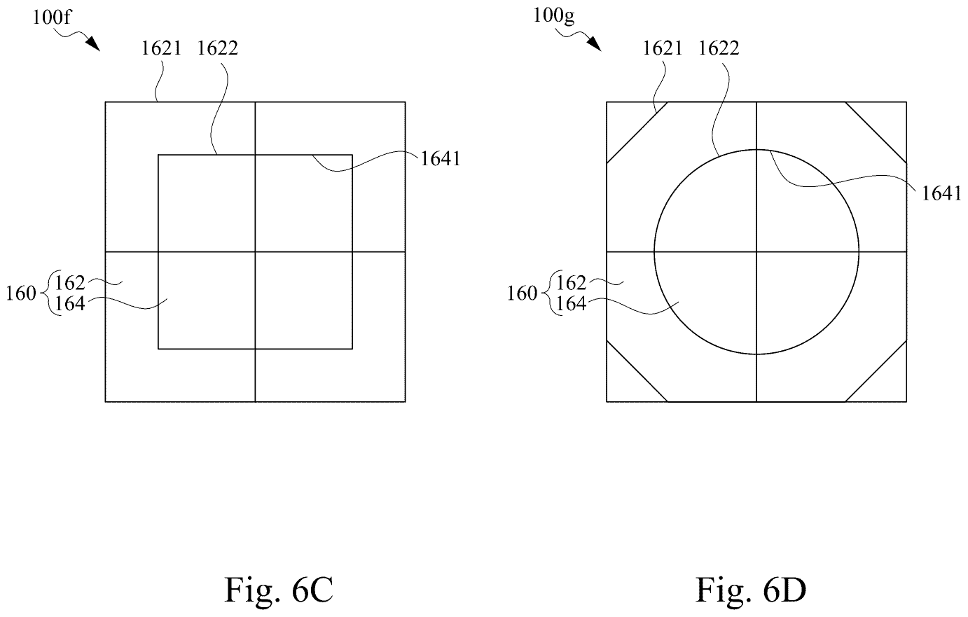

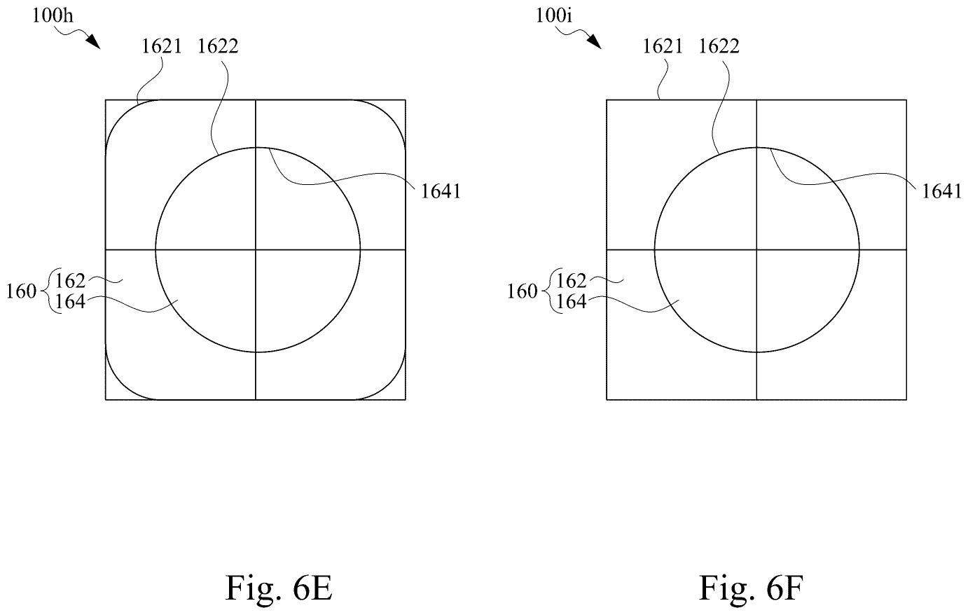

Reference is made FIG. 6A to FIG. 6F. FIG. 6A to FIG. 6F are top views of QPD units according to different embodiments of the disclosure. The shapes of the center lens 164 and ring-type lens 162 may have different variations. For example, as shown in the QPD unit 100d of FIG. 6A, the shape of the outer profile 1621 of the ring-type lens 162 is same as the shape of the inner profile 1622 of the ring-type lens 162, and the shape of the outer profile 1621 and the inner profile 1622 of the ring-type lens 162 is a polygon such as an octagon. The outer profile 1641 of the center lens 164 is same as the shape of the inner profile 1622 of the ring-type lens 162 which is also an octagon.

In some embodiments, as shown in the QPD unit 100e of FIG. 6B, the shape of the outer profile 1621 of the ring-type lens 162 is same as the shape of the inner profile 1622 of the ring-type lens 162, and the shape of the outer profile 1621 and the inner profile 1622 of the ring-type lens 162 is a square with rounding corners. The outer profile 1641 of the center lens 164 is same as the shape of the inner profile 1622 of the ring-type lens 162 which is also a square with rounding corners.

In some embodiments, as shown in the QPD unit 100f of FIG. 6C, the shape of the outer profile 1621 of the ring-type lens 162 is same as the shape of the inner profile 1622 of the ring-type lens 162, and the shape of the outer profile 1621 and the inner profile 1622 of the ring-type lens 162 is a square. The outer profile 1641 of the center lens 164 is same as the shape of the inner profile 1622 of the ring-type lens 162 which is also a square.

In some embodiments, as shown in the QPD unit 100g of FIG. 6D, the shape of the outer profile 1621 of the ring-type lens 162 is different from the shape of the inner profile 1622 of the ring-type lens 162. For example, the shape of the outer profile 1621 and the inner profile 1622 of the ring-type lens 162 is an octagon, and the inner profile 1622 of the ring-type lens 162 is a circle. The outer profile 1641 of the center lens 164 is same as the shape of the inner profile 1622 of the ring-type lens 162 which is also a circle.

In some embodiments, as shown in the QPD unit 100h of FIG. 6E, the shape of the outer profile 1621 of the ring-type lens 162 is different from the shape of the inner profile 1622 of the ring-type lens 162. For example, the shape of the outer profile 1621 and the inner profile 1622 of the ring-type lens 162 is a square with rounding corners, and the inner profile 1622 of the ring-type lens 162 is a circle. The outer profile 1641 of the center lens 164 is same as the shape of the inner profile 1622 of the ring-type lens 162 which is also a circle.

In some embodiments, as shown in the QPD unit 100i of FIG. 6F, the shape of the outer profile 1621 of the ring-type lens 162 is different from the shape of the inner profile 1622 of the ring-type lens 162. For example, the shape of the outer profile 1621 and the inner profile 1622 of the ring-type lens 162 is a square, and the inner profile 1622 of the ring-type lens 162 is a circle. The outer profile 1641 of the center lens 164 is same as the shape of the inner profile 1622 of the ring-type lens 162 which is also a circle.

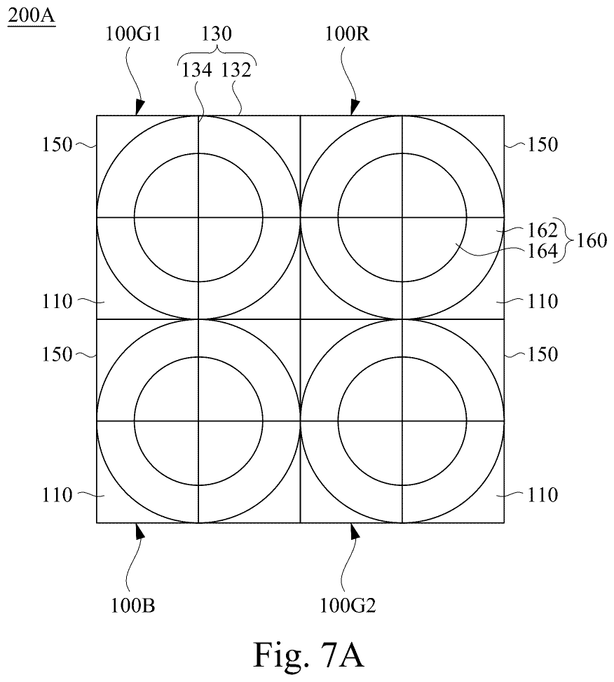

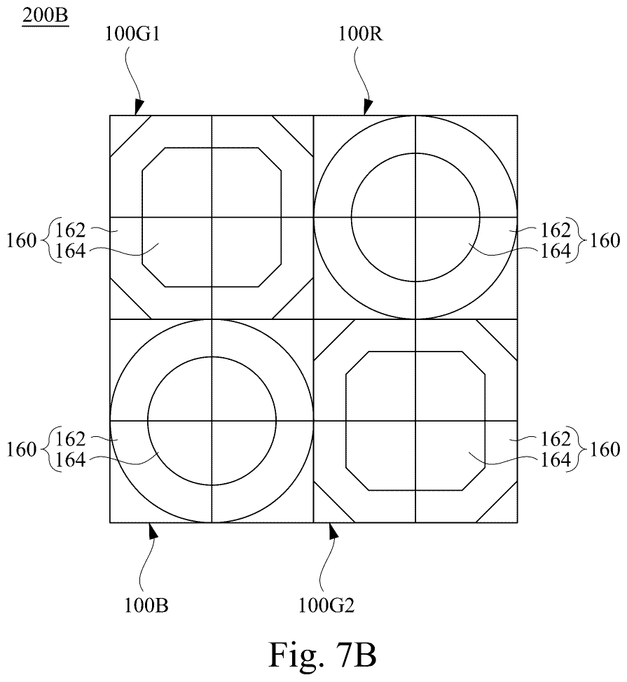

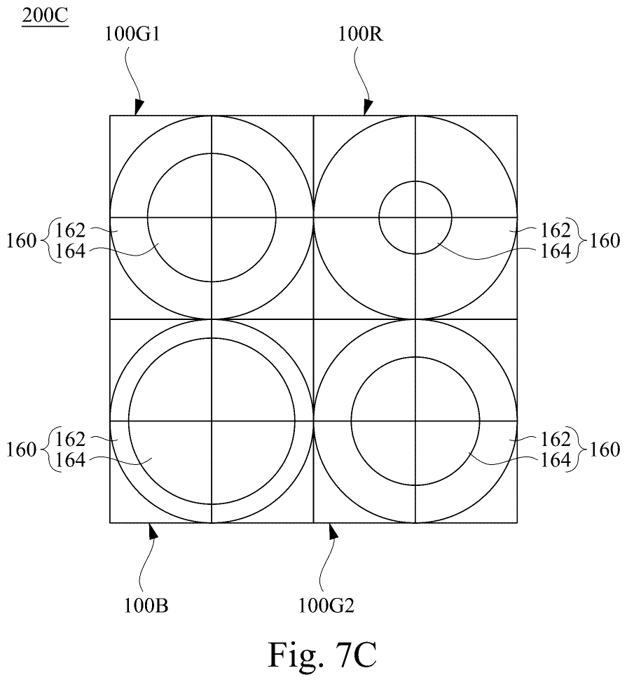

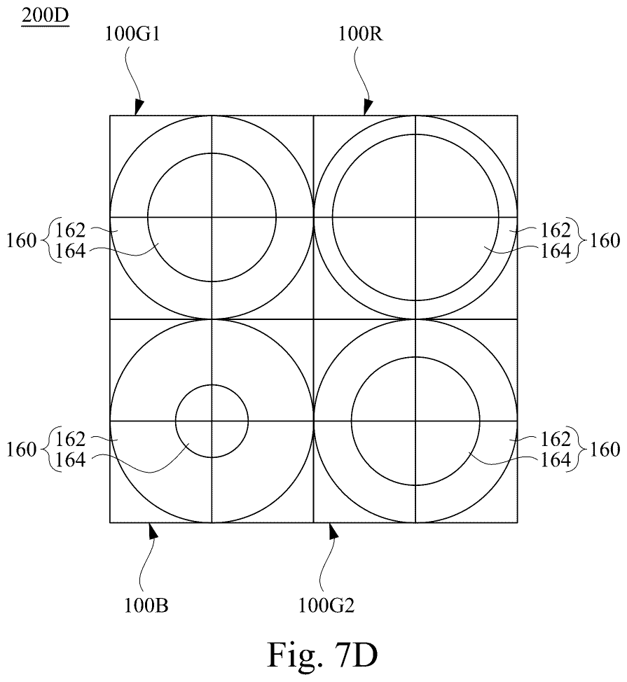

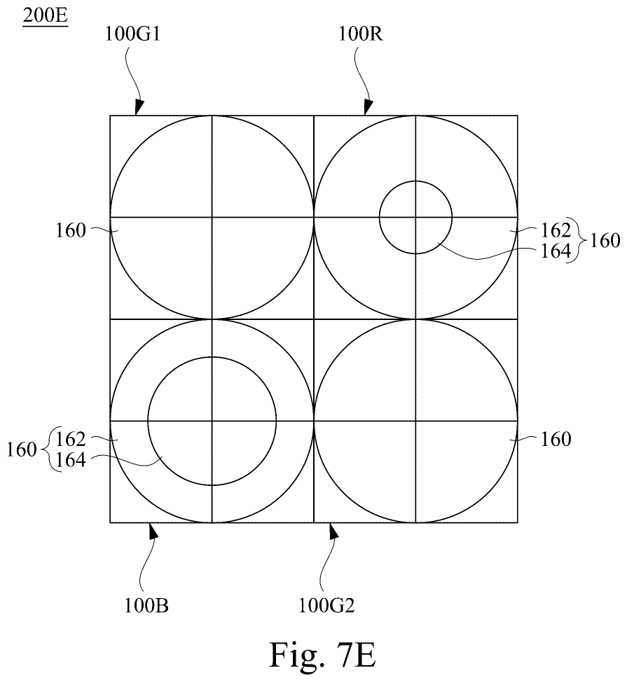

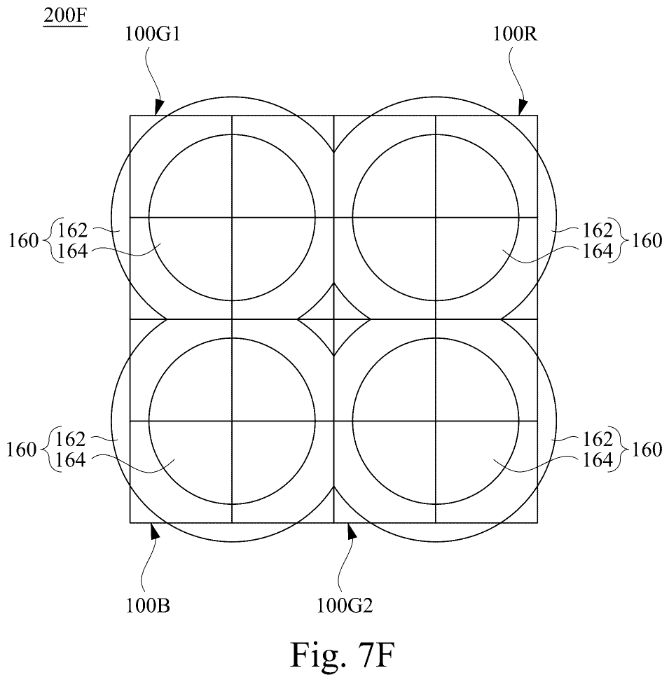

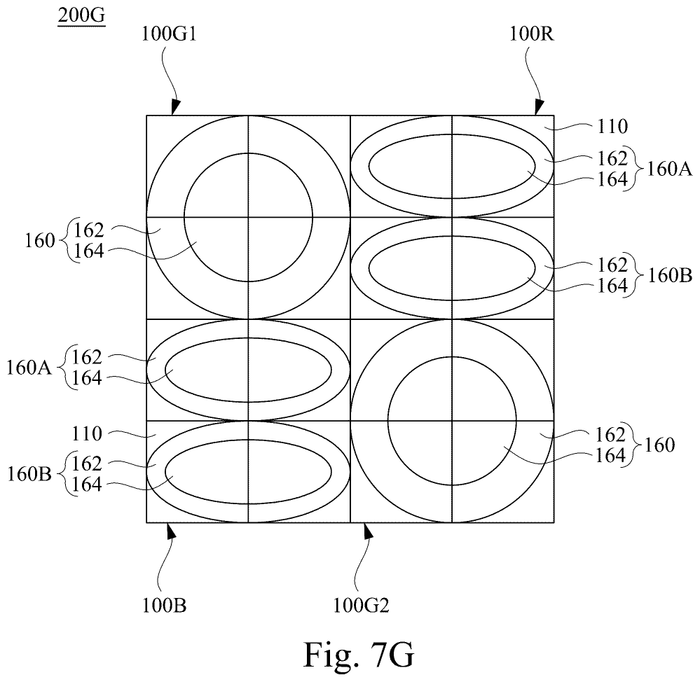

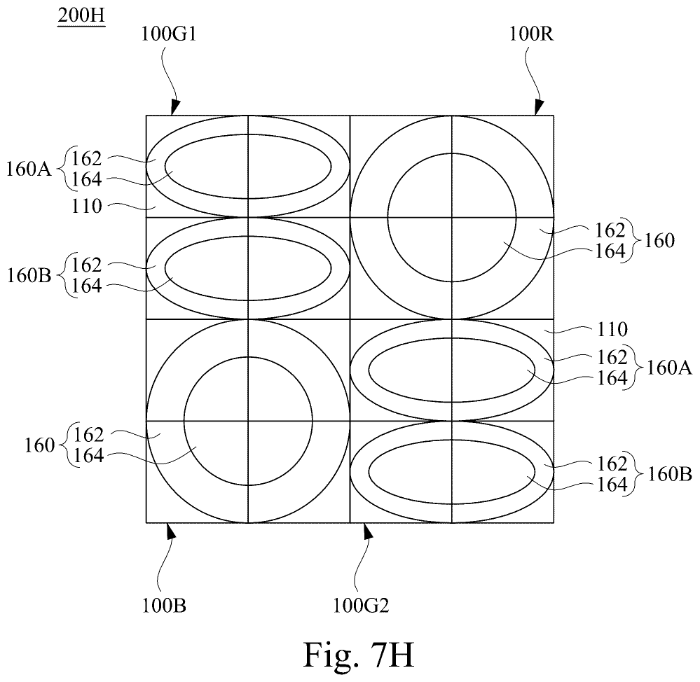

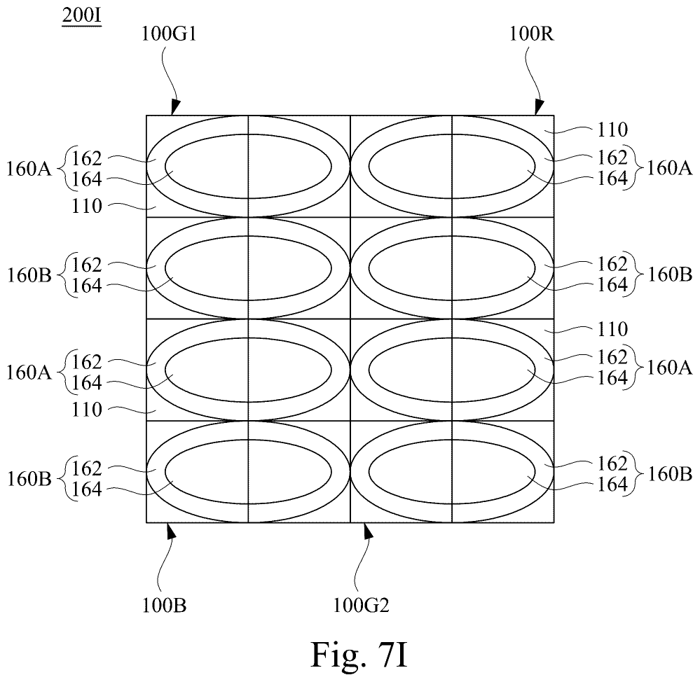

Reference is made to FIG. 7A to FIG. 7I. FIG. 7A to FIG. 7I are top views of sets of QPD units according to different embodiments of the disclosure. In some embodiments, each of the sets of QPD units 200A-200H include four QPD units arranged in a Bayer arrangement such as QPD unit 100R, QPD unit 100G1, QPD unit 100G2, and QPD unit 100B. Each of the QPD units 100R, 100G1, 100G2, and 100B includes the matrix of four photodiodes 110, the DTI structure 130 having the outer wall 132 surrounding the matrix of the photodiodes 110 and the inner wall 134 separating the photodiodes 110, the corresponding color filter 150 on the matrix of the photodiodes 110, and the optical component 160 on the color filter 150. The optical component 160 on corresponding color filter 150 which may have different waveband on different QPD units 100R, 100G1, 100G2, and 100B can be further designed to provide better performance.

In some embodiments, as shown in the set of QPD units 200A in FIG. 7A, the optical component 160 on different QPD units 100R, 100G1, 100G2, and 100B are substantially the same. Each optical component 160 includes the ring-type lens 162 and the center lens 164 surrounded by the ring-type lens 162, in which ring-type lens 162 has portions overlapping the outer wall 132 of the DTI structure 130.

In some embodiments, as shown in the set of QPD units 200B in FIG. 7B, the shape of the optical component 160 on the QPD unit 100R is different from the shape of the optical component 160 on the QPD unit 100G1. The shape of the optical component 160 on the QPD unit 100G1 is same as the shape of the optical component 160 on the QPD unit 100G2, and the shape of the optical component 160 on the QPD unit 100B can be the same or different from the shape of the optical component 160 on the QPD unit 100R.

In some embodiments, as shown in the set of QPD units 200C in FIG. 7C, the shape of the optical component 160 on different QPD units 100R, 100G1, 100G2, and 100B are substantially the same, and the filling ratio between the ring-type lens 162 and the center lens 164 can be varied. For example, the filling factor of the ring-type lens 162 of the optical component 160 on the QPD unit 100B is greater than the filling factor of the ring-type lens 162 of the optical component 160 on the QPD unit 100G1. The filling factor of the ring-type lens 162 of the optical component 160 on the QPD unit 100G1 is same as the filling factor of the ring-type lens 162 of the optical component 160 on the QPD unit 100G2. The filling factor of the ring-type lens 162 of the optical component 160 on the QPD unit 100R is smaller than the filling factor of the ring-type lens 162 of the optical component 160 on the QPD unit 100G1. That is, in some embodiments, the filling factor of the ring-type lens 162 of the optical component 160 is B>G>R.

In some embodiments, as shown in the set of QPD units 200D in FIG. 7D, the shape of the optical component 160 on different QPD units 100R, 100G1, 100G2, and 100B are substantially the same, and the filling ratio between the ring-type lens 162 and the center lens 164 can be varied. For example, the filling factor of the ring-type lens 162 of the optical component 160 on the QPD unit 100R is greater than the filling factor of the ring-type lens 162 of the optical component 160 on the QPD unit 100G1. The filling factor of the ring-type lens 162 of the optical component 160 on the QPD unit 100G1 is same as the filling factor of the ring-type lens 162 of the optical component 160 on the QPD unit 100G2. The filling factor of the ring-type lens 162 of the optical component 160 on the QPD unit 100B is smaller than the filling factor of the ring-type lens 162 of the optical component 160 on the QPD unit 100G1. That is, in some embodiments, the filling factor of the ring-type lens 162 of the optical component 160 is R>G>B.

In some embodiments, as shown in the set of QPD units 200E in FIG. 7E, the optical components 160 on the QPD units 100G1, 100G2 are different from the optical components 160 on the QPD units 100R, 100B. For example, the optical component 160 on the QPD unit 100G1 or 100G2 is a single sphere lenses, and the optical components 160 on the QPD units 100R, 100B each includes the ring-type lens 162 and the center lens 164. The filling factor of the ring-type lens 162 of the optical component 160 on the QPD unit 100B is greater than the filling factor of the ring-type lens 162 of the optical component 160 on the QPD unit 100R. That is, in some embodiments, the filling factor of the ring-type lens 162 of the optical component 160 is B>R>G=0.

In some embodiments, as shown in the set of QPD units 200F in FIG. 7F, The optical components 160 on the QPD units 100R, 100G1, 100G2, and 100B each includes the ring-type lens 162 and the center lens 164, and the shapes of the optical components 160 can be the same or different. In some embodiments, the ring-type lens 162 of the QPD units 100R, 100G1, 100G2, and 100B are merged.

In some embodiments, as shown in the set of QPD units 200G in FIG. 7G, the optical components 160 on the QPD units 100R, 100B are different from the optical components 160 on the QPD units 100G1, 100G2. The optical components 160 on the QPD units 100G1, 100G2 each includes the ring-type lens 162 and the center lens 164, and the center lens 164 overlaps the four photodiodes 110. The QPD units 100R, 100B each includes a first optical component 160A and a second optical component 160B. The first optical component 160A includes the ring-type lens 162 and the center lens 164, the center lens 164 overlaps two adjacent photodiodes 110, and the ring-type lens 162 and the center lens 164 have an ellipse shape. The second optical component 160B includes the ring-type lens 162 and the center lens 164, the center lens 164 overlaps another two photodiodes 110, and the ring-type lens 162 and the center lens 164 have an ellipse shape. Namely, the optical components 160 can correspond to the 2×2 array of photodiodes 110, and the first and second optical components 160A, 160B can correspond to the 2×1 array of photodiodes 110.

In some embodiments, as shown in the set of QPD units 200H in FIG. 7H, the optical components 160 on the QPD units 100R, 100B each includes the ring-type lens 162 and the center lens 164, and the center lens 164 overlaps the four photodiodes 110. Each of the QPD units 100G1, 100G2 includes a first optical component 160A and a second optical component 160B. The first optical component 160A includes the ring-type lens 162 and the center lens 164, the center lens 164 overlaps two adjacent photodiodes 110, and the ring-type lens 162 and the center lens 164 have an ellipse shape. The second optical component 160B includes the ring-type lens 162 and the center lens 164, the center lens 164 overlaps another two photodiodes 110, and the ring-type lens 162 and the center lens 164 have an ellipse shape.

In some embodiments, as shown in the set of QPD units 200I in FIG. 7I, the optical components 160 on the QPD units 100R, 100G1, 100G2, and 100B each includes a first optical component 160A and a second optical component 160B. The first optical component 160A includes the ring-type lens 162 and the center lens 164, the center lens 164 overlaps two adjacent photodiodes 110, and the ring-type lens 162 and the center lens 164 have an ellipse shape. The second optical component 160B includes the ring-type lens 162 and the center lens 164, the center lens 164 overlaps another two photodiodes 110, and the ring-type lens 162 and the center lens 164 have an ellipse shape.

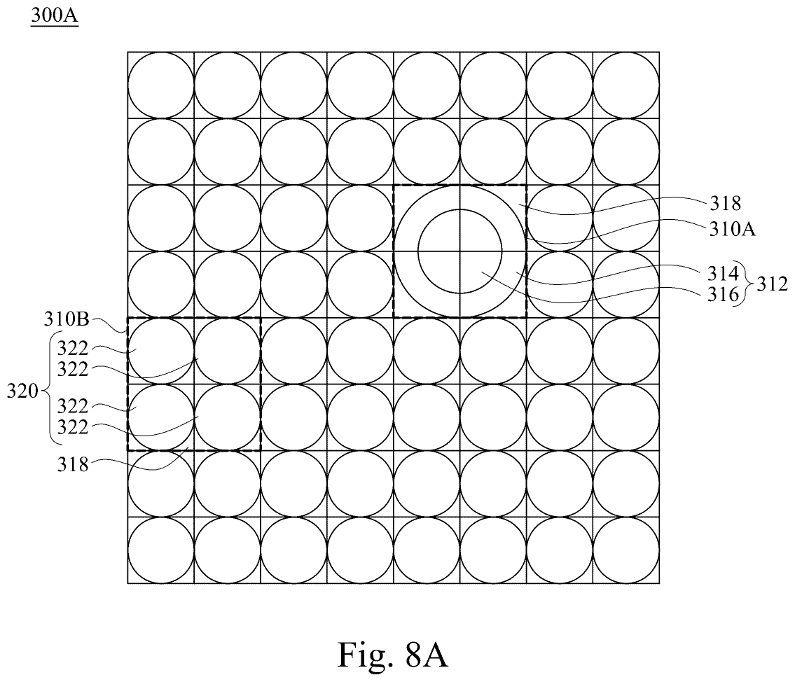

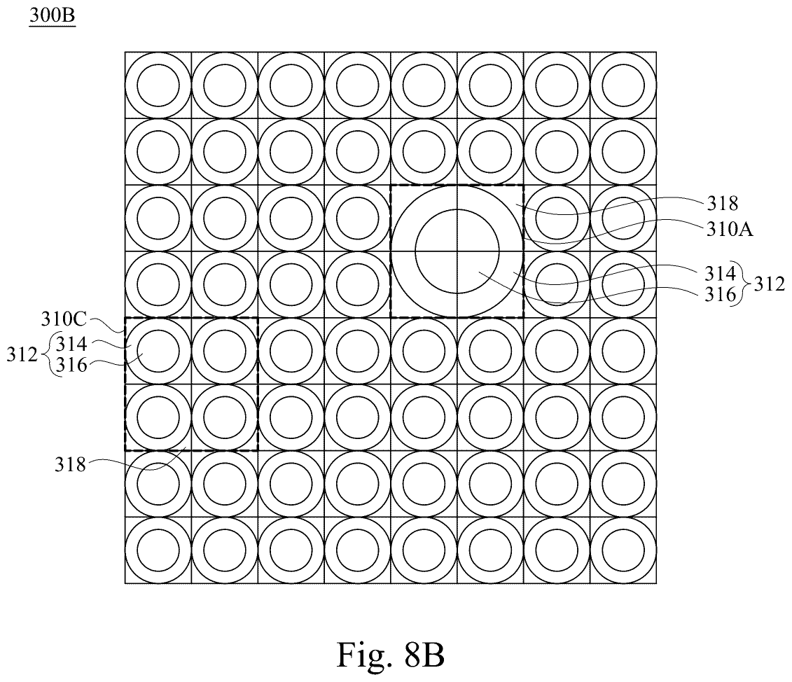

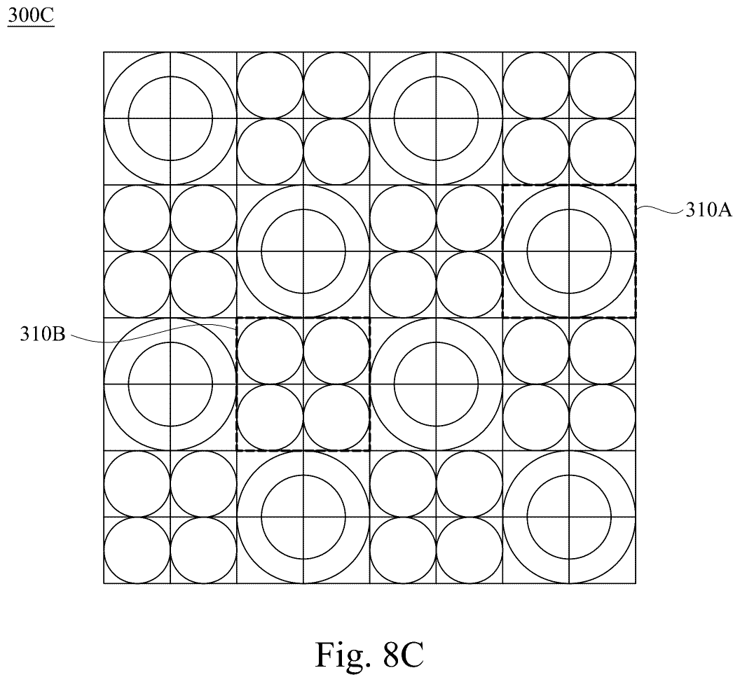

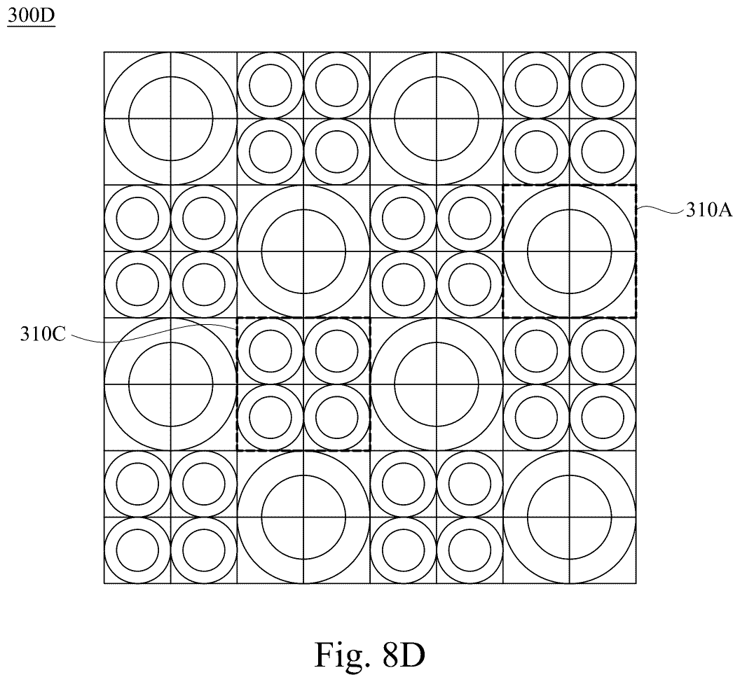

Reference is made to FIG. 8A to FIG. 8D. FIG. 8A to FIG. 8D are top views of an image sensor according to different embodiments of the disclosure. In some embodiments, as shown in the image sensor 300A of FIG. 8A, one of the QPD units such as the QPD unit 310A includes the optical component 312 including the ring-type lens 314 and the center lens 316, in which the center lens 316 overlaps the four photodiodes 318. Another one the QPD units such as the QPD unit 310B includes the optical component 320. The optical component 320 includes four sphere lenses 322 disposed on the four photodiodes 318, respectively.

In some embodiments, as shown in the image sensor 300B of FIG. 8B, one of the QPD units such as the QPD unit 310A includes the optical component 312 including the ring-type lens 314 and the center lens 316, in which the center lens 316 of the QPD unit 310A overlaps the four photodiodes 318. Another one the QPD units such as the QPD unit 310C includes four optical components 310. Each of the optical components 312 includes the ring-type lens 314 and the center lens 316. The center lens 316 of each optical component 310 of the QPD unit 310C overlaps one photodiode 318, respectively.

In some embodiments, as shown in the image sensor 300C of FIG. 8C, the QPD units 310A and the QPD unit 310B can be alternately arranged in row and in column. In some embodiments, as shown in the image sensor 300D of FIG. 8D, the QPD units 310A and the QPD unit 310C can be alternately arranged in row and in column.

It will be apparent to those skilled in the art that various modifications and variations can be made to the structure of the present disclosure without departing from the scope or spirit of the disclosure. In view of the foregoing, it is intended that the present disclosure cover modifications and variations of this invention provided they fall within the scope of the following claims and their equivalents.

What is claimed is:

1. An image sensor comprising:
a first quad phase detection (QPD) unit comprising:
four photodiodes arranged in a matrix of two rows and two columns;
a deep trench isolation structure comprising an outer wall surrounding the matrix of the photodiodes and an inner wall separating the photodiodes;
a grid disposed on the deep trench isolation structure;
a color filter disposed on the photodiodes and filled in the grid; and
an optical component disposed on the color filter, the optical component comprising a ring-type lens and a center lens surrounded by the ring-type lens, wherein the ring-type lens has portions overlapping the outer wall of the deep trench isolation structure.

2. The image sensor of claim 1, wherein the ring-type lens and the center lens are made of the same material, and a refractive index of the ring-type lens and the center lens is in a range from 1.5 to 2.5.

3. The image sensor of claim 1, wherein a height of the ring-type lens is less than a height of the center lens, and a dimension of the ring-type lens is less than a dimension of the center lens.

4. The image sensor of claim 1, wherein a ratio of a height of the ring-type lens to a height of the center lens is in a range from 45% to 65%.

5. The image sensor of claim 1, wherein a ratio of a dimension of the ring-type lens to a color pitch size is in a range from 14% to 25%, in which the color pitch size is a distance between centers of opposite portions of the grid.

6. The image sensor of claim 1, wherein a tangent line of the ring-type lens aligns a longitudinal axis of the outer wall of the deep trench isolation structure.

7. The image sensor of claim 1, wherein a tangent line of the ring-type lens is shifted relative to a longitudinal axis of the outer wall of the deep trench isolation structure, and a shifting between the tangent line of the ring-type lens and the longitudinal axis of the outer wall of the deep trench isolation structure is equal to or less than 50 nm.

8. The image sensor of claim 1, wherein a shape of an outer profile of the ring-type lens is same as a shape of an inner profile of the ring-type lens.

9. The image sensor of claim 1, wherein a shape of an outer profile of the ring-type lens is different from a shape of an inner profile of the ring-type lens.

10. The image sensor of claim 1, wherein the center lens overlaps the four photodiodes.

11. The image sensor of claim 1, wherein the center lens overlaps adjacent two of the photodiodes, and the image sensor further comprising an additional optical component disposed on the color filter and overlapping the other two of the photodiodes, the additional optical component comprising a ring-type lens and a center lens surrounded by the ring-type lens, wherein the ring-type lens has portions overlapping the outer wall of the deep trench isolation structure.

12. The image sensor of claim 1, further comprising:
a second QPD unit comprising:
four photodiodes arranged in a matrix of two rows and two columns;
a deep trench isolation structure comprising an outer wall surrounding the matrix of the photodiodes and an inner wall separating the photodiodes;
a color filter disposed on the photodiodes, wherein a waveband of the color filter of the second QPD unit is different from a waveband of the first QPD unit; and
an optical component disposed on the color filter.

13. The image sensor of claim 12, wherein the optical component of the second QPD unit comprises a ring-type lens and a center lens surrounded by the ring-type lens, wherein the ring-type lens has portions overlapping the outer wall.

14. The image sensor of claim 13, wherein the ring-type lens of the first QPD unit is merged with the ring-type lens of the second QPD unit.

15. The image sensor of claim 13, wherein a shape of the optical component of the first QPD unit is different from the optical component of the second QPD unit.

16. The image sensor of claim 13, wherein a filling factor of the ring-type lens of the first QPD unit is different from a filling factor of the ring-type lens of the second QPD unit.

17. The image sensor of claim 12, wherein the optical component of the second QPD unit comprises four sphere lenses disposed on the photodiodes, respectively.

18. The image sensor of claim 12, wherein the optical component of the second QPD unit comprises a single sphere lenses disposed on the photodiodes.

19. The image sensor of claim 1, further comprising:
a second QPD unit comprising:
four photodiodes arranged in a matrix of two rows and two columns;
a deep trench isolation structure comprising an outer wall surrounding the matrix of the photodiodes and an inner wall separating the photodiodes;
a color filter disposed on the photodiodes, wherein a waveband of the color filter of the second QPD unit is different from a waveband of the first QPD unit;
a first optical component disposed on the color filter and above adjacent two of the photodiodes, the first optical component comprises a ring-type lens and a center lens surrounded by the ring-type lens, wherein the ring-type lens has portions overlapping the outer wall; and
a second optical component disposed on the color filter and above another two of the photodiodes, the second optical component comprises a ring-type lens and a center lens surrounded by the ring-type lens, wherein the ring-type lens has portions overlapping the outer wall.

20. The image sensor of claim 1, further comprising:
a second QPD unit comprising:
four photodiodes arranged in a matrix of two rows and two columns;
a deep trench isolation structure comprising an outer wall surrounding the matrix of the photodiodes and an inner wall separating the photodiodes;
a color filter disposed on the photodiodes, wherein a waveband of the color filter of the second QPD unit is different from a waveband of the first QPD unit; and
four optical components disposed on the color filter and above the photodiodes, respectively, each of the optical components comprising a ring-type lens and a center lens surrounded by the ring-type lens, wherein the ring-type lens has a portion overlapping the outer wall.
